(19) United States
(12) Patent Application Publication
(10) Pub. No.: US 2017/0215300 A1
(43) Pub. Date: Jul. 27, 2017

(54) Z-STEPPED PARALLEL FAN FRU AND METHOD

(71) Applicant: Brocade Communications Systems, Inc., San Jose, CA (US)

(72) Inventor: Gary Heslop SALMOND, Los Gatos, CA (US)

(21) Appl. No.: 15/279,082

(22) Filed: Sep. 28, 2016

Related U.S. Application Data
(60) Provisional application No. 62/287,736, filed on Jan. 27, 2016.

(51) Int. Cl. H05K 7/20; F04D 29/52; F04D 29/54; F04D 25/16; F04D 19/00

(52) U.S. Cl. CPC H05K 7/20172; F04D 25/166; F04D 19/002; F04D 29/541; F04D 29/522; H05K 7/20145

(57) ABSTRACT

A fan module includes a front face, a rear face, a first fan including a front face fan port facing towards the front face, and a second fan including a rear face fan port facing towards the rear face. The first fan is between the rear face and the second fan. A module port is at the rear face and spaced apart from the first fan. A baffle isolates the front face fan port of the first fan from the rear face fan port of the second fan. In this manner, two parallel air flow pathways are created by the fans through the fan module.

### RELATED APPLICATIONS

This application claims the benefit of U.S. Provisional Application No. 62/287,736 filed on Jan. 27, 2016, entitled “Z-STEPPED PARALLEL FAN FRU AND METHOD” of Gary Heslop Salmond, which is incorporated herein by reference in its entirety.

### BACKGROUND

Field

The present application relates to the field of electronics, and more particularly, to structures for cooling electronic devices and related methods.

Description of the Related Art

An electronic device such as a switch includes an enclosure housing a plurality of electronic components therein. As the complexity of the electronic device increases, the density of the electronic components located within the enclosure also increases. The increased density of electronic components increases the amount of heat generated within the enclosure. This heat must be removed to avoid overheating of the electronic components and the associated failure thereof.

### SUMMARY

A fan module includes a front face, a rear face, a first fan including a front face fan port facing towards the front face, and a second fan including a rear face fan port facing towards the rear face. The first fan is between the rear face and the second fan. A module port is at the rear face and spaced apart from the first fan.

A baffle isolates the front face fan port of the first fan from the rear face fan port of the second fan. In this manner, two parallel air flow pathways are created by the fans through the fan module. Each air flow pathway is sufficiently sized to minimize impedance on airflow through the fans. Accordingly, the fan module enhances airflow and cooling through an electronic device.

Further, in the event that one of the fans fails, airflow along the air flow pathway associated with the operational fan is unimpeded. Accordingly, the fan module continues to provide adequate cooling even in the event of failure of one of the fans.

Further, by stepping the fans, the parallel airflow pathways are achieved without doubling the width of the fan module. In one embodiment, the space beside the second fan is used to locate a mounting structure allowing the fan module to be the width of a standard single wide fan FRU plus the width of the standard sidewall divider that extends the length of the single wide fan FRU. This increases the total airflow area of the fan module thus further enhancing airflow through the electronic device.

These and other features in accordance with various embodiments will be more readily apparent from the detailed description set forth below taken in conjunction with the accompanying drawings.

### BRIEF DESCRIPTION OF THE DRAWINGS

FIG. 1 is a top plan view of an electronic device including a plurality a Z-stepped parallel fan field replaceable units (FRUs) in accordance with one embodiment.

FIG. 2 is a top perspective view of the electronic device of FIG. 1 in accordance with one embodiment.

FIG. 3 is an exploded perspective view of the electronic device of FIGS. 1 and 2 in accordance with one embodiment.

FIG. 4 is a perspective view of a single Z-stepped parallel fan FRU of the electronic device of FIGS. 1-3 in accordance with one embodiment.

FIG. 5 is a top plan view of the Z-stepped parallel fan FRU of FIG. 4 in accordance with one embodiment.

FIG. 6 is an exploded perspective view of a Z-stepped parallel fan FRU in accordance with another embodiment.

FIG. 7 is a top plan view of the Z-stepped parallel fan FRU of FIG. 6 in accordance with one embodiment.

FIG. 8 is a side plan view of the Z-stepped parallel fan FRU of FIG. 6 in accordance with one embodiment.

FIG. 9 is a rear plan vim of the Z-stepped parallel fan FRU of FIG. 6 in accordance with one embodiment.

FIG. 10 is a front plan view of the Z-stepped parallel fan FRU of FIG. 6 in accordance with one embodiment.

FIG. 11 is a bottom plan view of the Z-stepped parallel fan FRU of FIG. 6 in accordance with one embodiment.

FIG. 12 is an enlarged perspective view of a baffle of the Z-stepped parallel fan FRU of FIG. 6 in accordance with one embodiment.

FIG. 13 is a top plan view of the baffle of FIG. 12 in accordance with one embodiment.

FIG. 14 is a bottom plan view of the baffle of FIG. 12 in accordance with one embodiment.

FIG. 15 is a perspective view of a chassis base including a plurality of sidewall dividers mounted thereto in accordance with one embodiment.

FIG. 16 is an enlarged perspective view of a sidewall divider of FIG. 15 in accordance with one embodiment.

FIG. 17 is a top plan view of the sidewall divider of FIG. 16 in accordance with one embodiment.

FIG. 18 is a top plan view of the sidewall divider of FIG. 17 having the Z-stepped parallel fan FRU of FIG. 6 being mounted thereto in accordance with one embodiment.

FIGS. 19-20 are perspective and top plan views, respectively, of a Z-stepped parallel fan FRU having reverse air flow restrictors for restricting reverse airflow upon a fan failure condition in accordance with one embodiment.

In the following description, the same or similar elements are labeled with the same or similar reference numbers.

### DETAILED DESCRIPTION

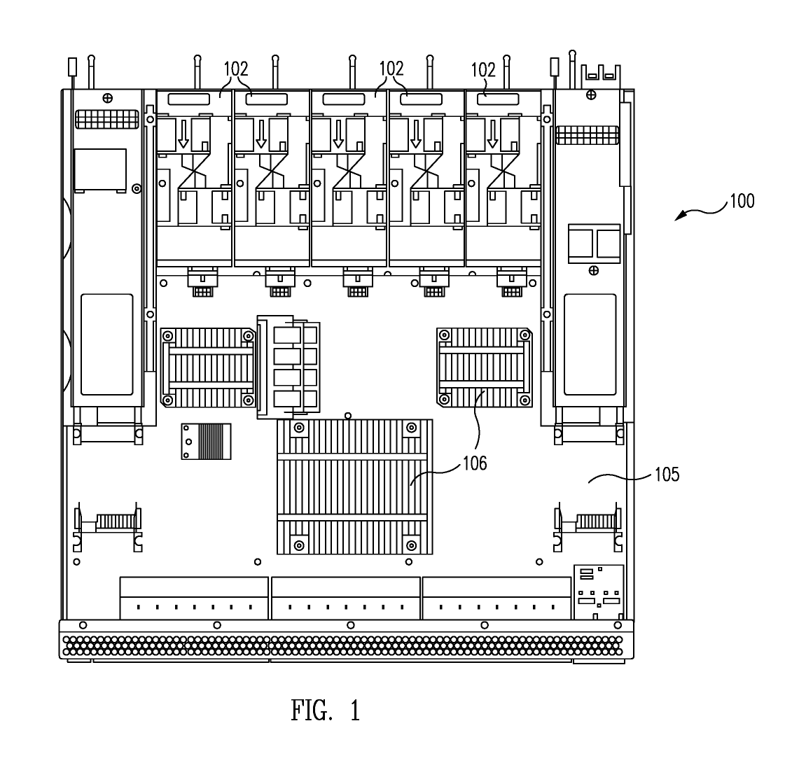

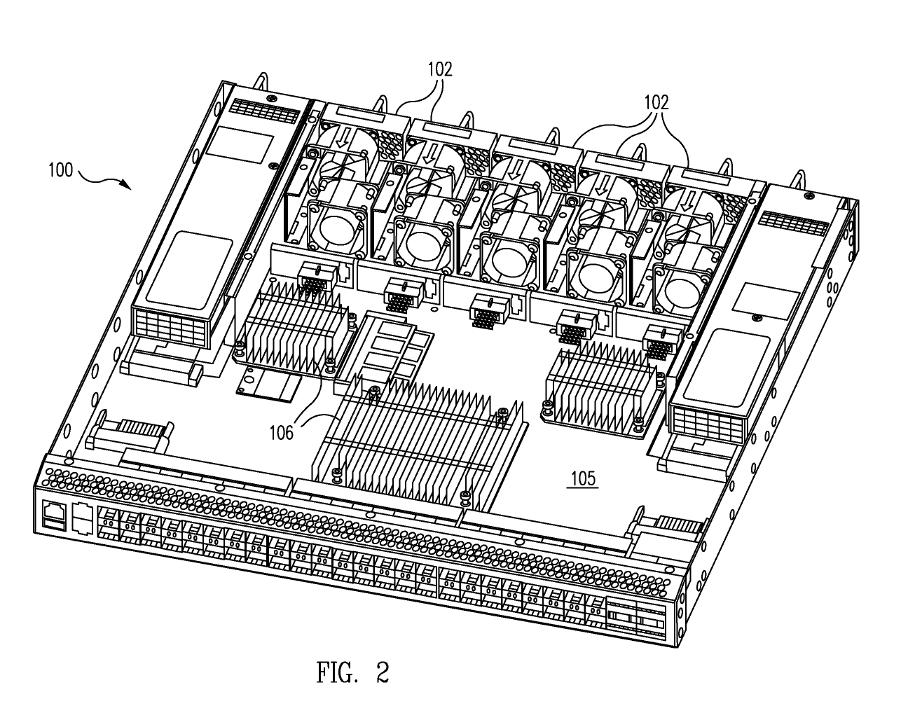

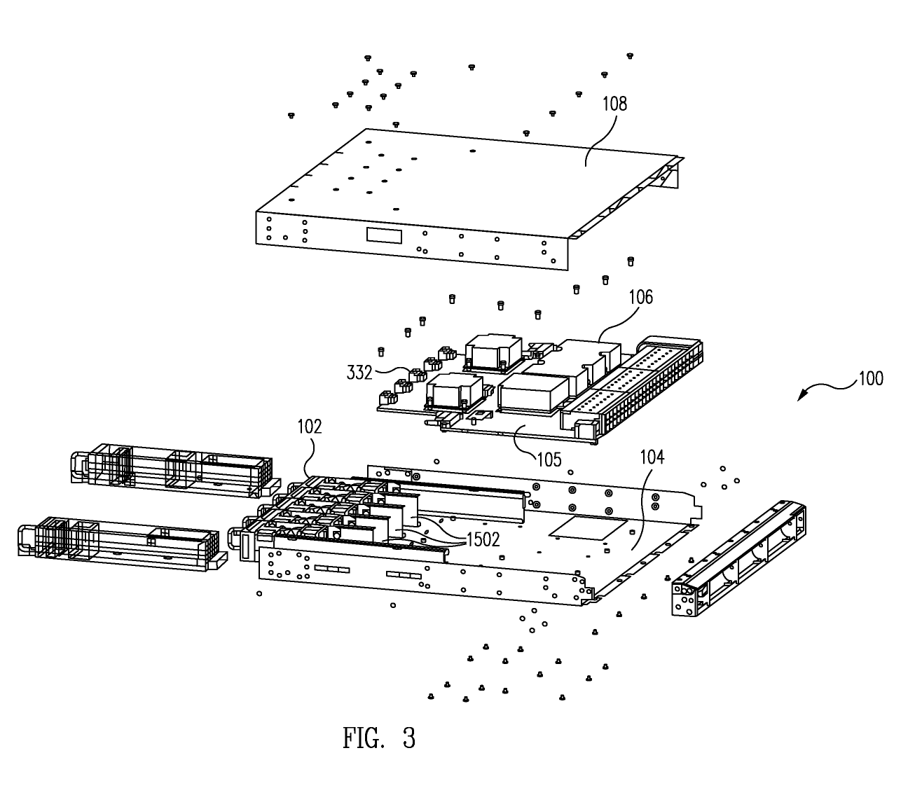

FIG. 1 is a top plan view of an electronic device 100 including a plurality of Z-stepped parallel fan field replaceable units (FRUs) 102 in accordance with one embodiment. FIG. 2 is a top perspective view of electronic device 100 of FIG. 1 in accordance with one embodiment. FIG. 3 is an exploded perspective view of electronic device 100 of FIGS. 1 and 2 in accordance with one embodiment. In FIGS. 1 and 2, a cover 108 of electronic device 100 has been removed to allow visualization of the features within electronic device 100. Z-stepped parallel fan FRUs 102 are sometimes called stepped or staggered parallel fan FRUs 102.

Electronic device 100 includes a chassis base 104 to which a printed circuit board 105 including one or more heat generating electronic components 106 are mounted. During operation, electronic components 106 generate heat. This heat must be removed from electronic device 100 to avoid overheating of electronic components 106.

In one embodiment, electronic device 100 includes a fixed form-factor chassis, e.g., a chassis having a defined size such as a 1 rack unit (1 RU) size. In accordance with one embodiment, 1000 watts of heat is generated by electronic components 106 and removed although more or less heat is generated in other embodiments.

To facilitate removal of heat from electronic device 100, electronic device 100 includes at least one, and in this embodiment, a plurality of Z-stepped parallel fan FRUs 102, e.g., five.

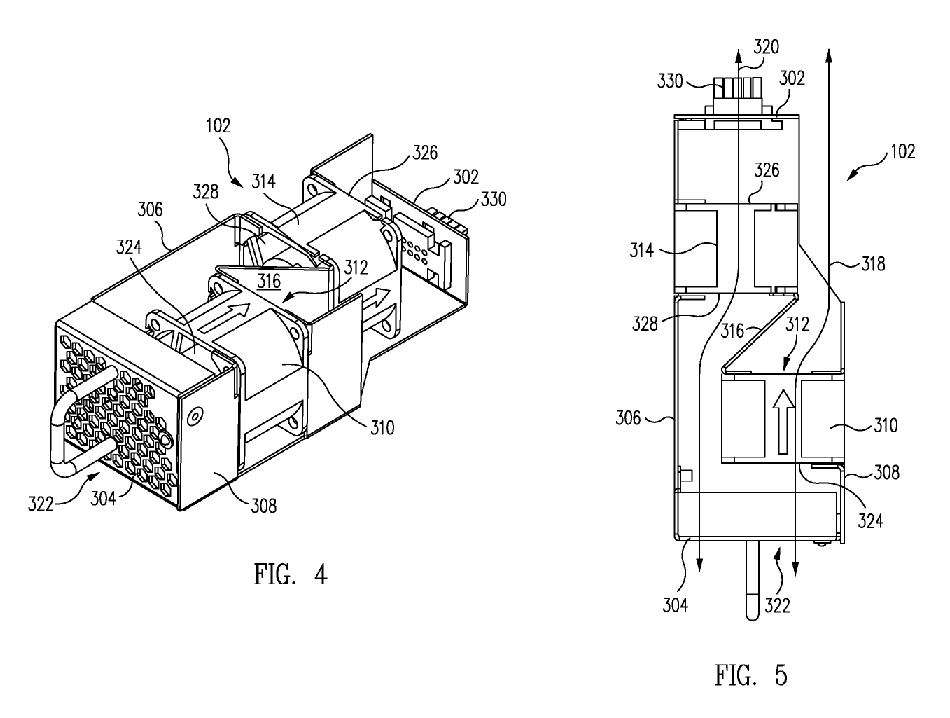

FIG. 4 is a perspective view of a single Z-stepped parallel fan FRU 102 of electronic device 100 of FIGS. 1-3 in accordance with one embodiment. FIG. 5 is a top plan view of Z-stepped parallel fan FRU 102 of FIG. 4 in accordance with one embodiment.

Z-stepped parallel fan FRU 102 includes a front face 302, a rear face 304, a first module side 306, and a second module side 308. Z-stepped parallel fan FRU 102 further includes a first fan 310 comprising a front face fan port 312 facing towards front face 302. Z-stepped parallel fan FRU 102 further include a second fan 314. First fan 310 is between rear face 304 and second fan 314.

Z-stepped parallel fan FRU 102 further includes a baffle 316 isolating from face fan port 312 of first fan 310 from second fan 314. Accordingly, two parallel air flow pathways 318, 320 are created by fans 310, 314 through Z-stepped parallel fan FRU 102.

Each air flow pathway 318, 320 is sufficiently sized to minimize impedance on airflow through fans 310, 314. Accordingly, Z-stepped parallel fan FRU 102 enhances airflow and cooling through electronic device 100.

Further, in the event that one of fans 310, 314 fails, airflow along the air flow pathway 318 or 320 associated with the operational fan 310 or 314 is unimpeded. Accordingly, Z-stepped parallel fan FRU 102 continues to provide adequate cooling even in the event of failure of one of fans 310, 314. This is in contrast to a series arrangement of fans, where failure of one fan creates a large impedance to airflow through the other fan.

Further, by stepping fans 310, 314, parallel airflow pathways 318, 320 are achieved without doubling the width of Z-stepped parallel fan FRU 102. In one embodiment, the space beside second fan 314 is used to locate a mounting structure (see FIG. 18 as an example) therein allowing stepped parallel fan FRU 102 to be the width of a standard single wide fan FRU plus the width of the standard sidewall divider that extends the length of the single wide fan FRU. Accordingly, Z-stepped parallel fan FRUs 102 are mounted side by side without providing a space for a sidewall divider between Z-stepped parallel fan FRUs 102 or a minimal width sidewall divider, e.g., the thickness of sheet metal. This increases the total airflow area of Z-stepped parallel fan FRUs 102 thus further enhancing airflow through electronic device 100. More particularly, a width of a module port 322 at rear face 304 is larger than a standard single vide fan FRU. Module port 322 is spaced apart from first fan 310.

Air flow pathway 318, 320 are sometimes called a first fan airflow pathway 318 and a second fan airflow pathway 320, respectively. First fan airflow pathway 318 is defined by and extends from module port 322 to first fan 310, through first fan 310, between baffle 316 and second module side 308, and between second fan 314 and second module side 308 (and/or a sidewall divider such s that illustrated in FIG. 18). Second fan airflow pathway 320 is defined by and extends from module port 322 and between first fan 310 and first module side 306, between baffle 316 and first module side 306, and through second fan 314.

First fan 310 further includes a rear face fan port 324. Second fan 314 is similar to first fan 310 and includes a front face fan port 326 and a rear face tan port 328. Baffle 316 isolates front face fan port 312 of first fan 310 from rear face fan port 328 of second fan 314.

In one embodiment, first fan 310 and second fan 314 are axial fans having fan blades on axes perpendicular to ports 312, 324, 326. 328. Accordingly, air flows from rear face fan ports 324, 328 to front face fan ports 312, 326 or vice versa. In accordance with one embodiment, air flows along air flow pathways 318, 320 from module port 322 at rear face 304 through fans 310, 314 and exits at front face 302.

In another embodiment, air flows from front face fan ports 312, 326 to rear face fan ports 324, 328. In accordance with this embodiment, air flows along air flow pathways 318, 320 from front face 302 through fans 310, 314 and exits through module port 322 at rear face 304.

Z-stepped parallel fan FRU 102 further includes a connector 330 which mates with a corresponding connector 332 (illustrated in FIG. 3) of printed circuit board 105. Power is provided through connector 330 to drive Z-stepped parallel fan FRU 102 including fans 310, 314.

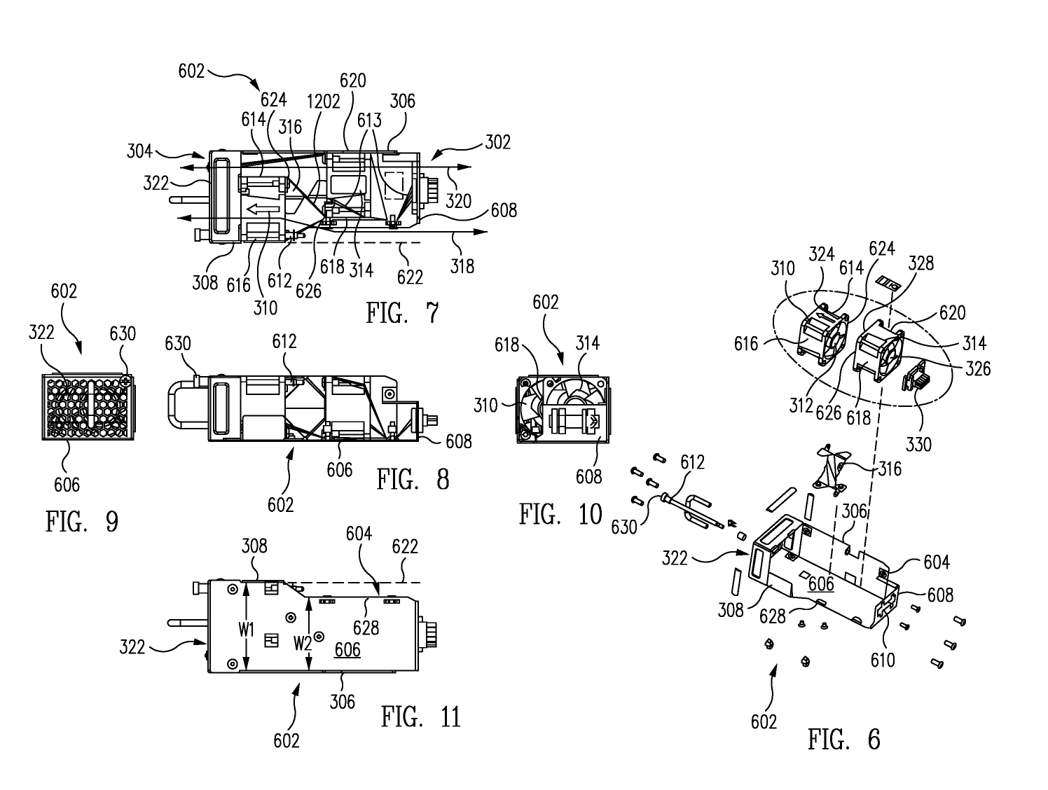

FIG. 6 is an exploded perspective view of a Z-stepped parallel fan FRU 602 in accordance with another embodiment. Z-stepped parallel fan FRU 602 of FIG. 6 is similar to Z-stripped parallel fan FRU 102 of FIGS. 4-5 and only various features and significant differences are discussed below.

FIG. 7 is a top plan view of Z-stepped parallel fan FRU 602 of FIG. 6 in accordance with one embodiment. FIG. 8 is a side plan view of Z-stepped parallel fan FRU 602 of FIG. 6 in accordance with one embodiment. FIG. 9 is a rear plan view of Z-stepped parallel fan FRU 602 of FIG. 6 in accordance with one embodiment. FIG. 10 is a front plan view of Z-stepped parallel fan FRU 602 of FIG. 6 in accordance with one embodiment. FIG. 11 is a bottom plan view of Z-stepped parallel fan FRU 602 of FIG. 6 in accordance with one embodiment.

Referring now to FIGS. 6-11, Z-stepped parallel fan FRU 602 includes a fan FRU chassis 604, e.g., a steel chassis. Fan FRU chassis 604 includes a fan chassis base 606. Extending perpendicularly from fan chassis base 606 is module port 322, e.g., a plate having an array of openings, at rear face 304. Extending perpendicular from fan chassis base 606 is a front lace plate 608 at front face 302. Front face plate 608 has an opening 610 therein to accommodate connector 330. Extending perpendicularly from fan chassis base 606 is first module side 306. First module side 306 extends perpendicularly from front face 302 to rear face 304.

Although the terms perpendicular, parallel, planar, and similar term are used herein to describe various features, it is to be understood that the features may not be exactly perpendicular, parallel or planar, e.g., due to manufacturing tolerances, and/or may include various protrusions or indentations.

Baffle 316, first fan 310, second fin 314, connector 330 and a threaded mounting pin 612 are mounted to fan FRU chassis 604, e.g., using screw, rivets, adhesive, or other mounting structures. Wiring 613 extends from connector 330 to fans 310, 314 and other components, e.g., a status indicator light.

First fan 310 include an inner side 614 and an outer side 616. Outer side 616 is located at second module side 308. Inner side 614 is spaced apart from first module side 306 thus defining a portion of air flow pathway 320 therebetween.

Similarly, second fan 314 include an inner side 618 and an outer side 620. Outer side 620 is located at first module side 306. Inner side 618 is spaced apart from a plane 622 (indicated in a dashed line) parallel to second module side 308 thus defining a portion of air flow pathway 318 therebetween.

As illustrated in FIG. 10, when viewed along the axial direction of fans 310, 314, e.g., from front face 302, fans 310, 314 overlap on another. More particularly, inner side 618 of second fan 314 is directly in front of from face fan port 312 of first fan 310. Similarly, inner side 614 of first fan 310 is directly behind rear face fan port 328 of second fan 314. By overlapping fans 310, 314, the width of Z-stepped parallel fan FRU 602 is minimized as compared to a side by side arrangement of fans 310, 314, i.e., is less than the combined width of fans 310, 314.

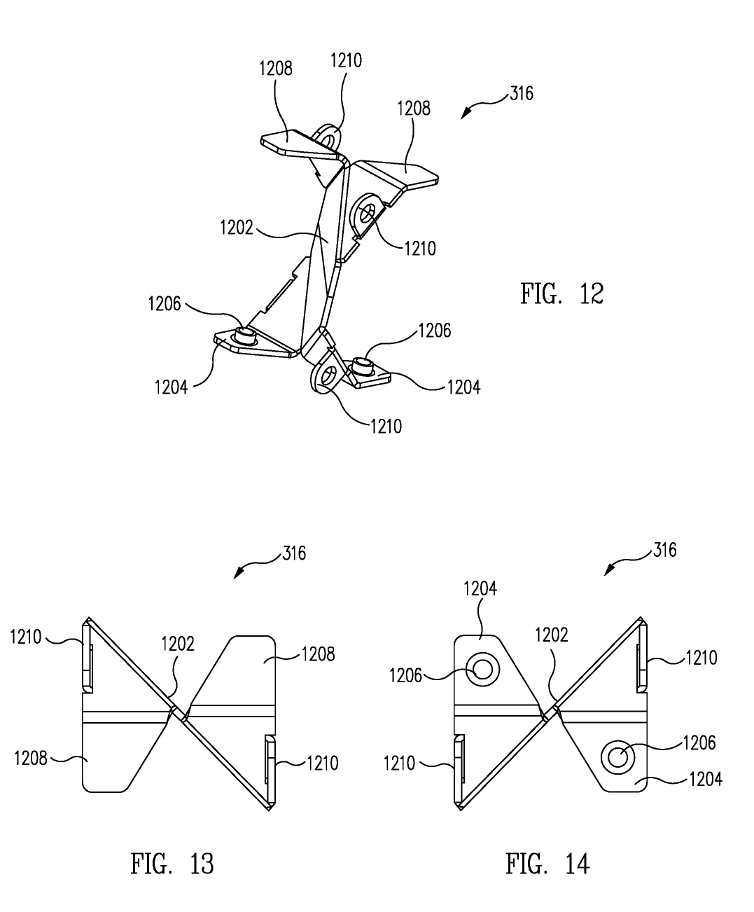

FIG. 12 is an enlarged perspective view of baffle 316 of Z-stepped parallel fan FRU 602 of FIG. 6 in accordance with one embodiment. FIG. 13 is a top plan view of baffle 316 of FIG. 12 in accordance with one embodiment. FIG. 14 is a bottom plan view of baffle 316 of FIG. 12 in accordance with one embodiment.

Paying particular attention to FIGS. 6-7, 12-13, baffle 316 includes a planar airflow diversion plate 1202. As illustrated in FIG. 7, airflow diversion plate 1202 extends at an angle, e.g., 45 degrees, between fans 310, 312, More particularly, airflow diversion plate 1202 extends from an edge 624 at the intersection of front face fan port 312 and inner side 614 of first fan 310 to an edge 626 at the intersection of rear face fan port 328 and inner side 618 of second fan 314.

Baffle 316 further includes baffle mounting flanges 1204 having mounting apertures 1206, e.g., threaded apertures, therein. Baffle mounting flanges 1204 are perpendicular to airflow diversion plate 1202. Baffle mounting flanges 1204 are mounted to fan chassis base 606 of fan FRU chassis 604, e.g., with screws, within mounting apertures 1206.

Baffle 316 further includes cover support flanges 1208. Cover support flanges 1208 are perpendicular to airflow diversion plate 1202. Cover support flanges 1208 contact and support cover 108 (see FIG. 3) or are slightly spaced therefrom. Note cover 108 seals the top of Z-stepped parallel fan FRU 602 including parallel airflow pathways 318, 320.

Baffle 316 further includes fan mounting brackets 1210 far mounting to fans 310, 314.

Referring again to FIGS. 6-11, to facilitate mounting of Z-stepped parallel fan FRU 602 within electronic device 100, Z-stepped parallel fan FRU 602 includes threaded mounting pin 612 and a cutout 628 in fan chassis base 606. Threaded mounting pin 612 includes a knob 630 that protrudes from module port 322 and rear face 304 so that a user can grab and twist threaded mounting pin 612 to thread/unthread threaded mounting pin 612 from a sidewall divider, sometimes called a mounting structure, as discussed further below.

Cutout 628 accommodates the sidewall divider as also further discussed below. More particularly, fan chassis base 606 tapers inward from second module side 308 to form cutout 628, Z-stepped parallel fan FRU 602 has a first width W1 between first and second module sides 306, 308 approximately equal to the width of a standard single wide fan FRU plus the width of the standard sidewall divider. Z-stepped parallel fan FRU 602 has a second width W2 between first module side 306 and cutout 628 that is less than the first width W1.

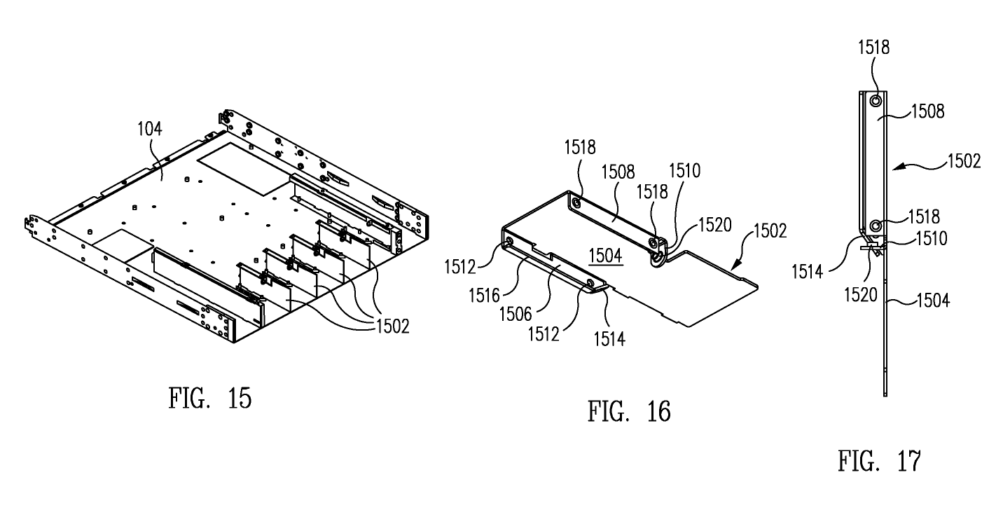

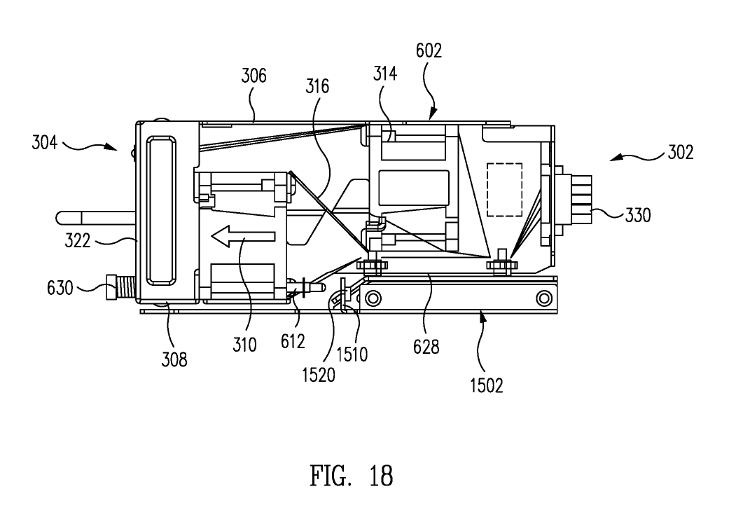

FIG. 15 is a perspective view of chassis base 104 including a plurality of sidewall dividers 1502 mounted thereto in accordance with one embodiment. FIG. 16 is an enlarged perspective view of a sidewall divider 1502 of FIG. 15 in accordance with one embodiment. FIG. 17 is a top plan view of sidewall divider 1502 of FIG. 16 in accordance with one embodiment. FIG. 18 is a top plan view of sidewall divider 1502 of FIG. 17 having Z-stepped parallel fan FRU 602 of FIG. 6 being mounted thereto in accordance with one embodiment.

Sidewall divider 1502 includes a planar central plate 1504, e.g., having the thickness of sheet-metal. Sidewall divider 1502 further includes a sidewall divider mounting bracket 1506, a cover mounting bracket 1508, and a Z-stepped parallel fan FRU mounting bracket 1510.

Sidewall divider mounting bracket 1506 extends perpendicularly from central plate 1504 at a lower edge thereof. Sidewall divider mourning bracket 1506 includes mounting apertures 1512 therein, Sidewall divider mounting bracket 1506 is mounted to chassis base 104, e.g., with screws or rivets, within mounting apertures 1512. Sidewall divider mounting bracket 1506 further includes a rear facing taper 1514 that guides Z-stepped parallel fan FRU 602 into position during insertion. Sidewall divider mounting bracket 1506 further includes lip 1516 extending upwards that prevents Z-stepped parallel fan FRU 602 from sliding on top of sidewall divider mounting bracket 1506.

Cover mounting bracket 1508 extends perpendicularly from central plate 1504 at an upper edge thereof. Cover mounting bracket 1508 includes mounting apertures 1518 therein. Cover 108 (see FIG. 3) is mounted to cover mounting bracket 1508, e.g., with screws, within mounting apertures 1518.

Z-stepped parallel fan FRU mounting bracket 1510 also extends perpendicularly from central plate 1504 and perpendicular to sidewall divider mounting bracket 1506 and cover mounting bracket 1508. Z-stepped parallel fan FRU mounting bracket 1510 includes an aperture 1520 therein, e.g., a threaded aperture. Aperture 1520 is configured to engage threaded mounting pin 612, e.g., threads thereof.

To mount Z-stepped parallel fan. FRU 602, Z-stepped parallel fan FRU 602 is inserted between two sidewall dividers 1502. Taper 1514 guides Z-stepped parallel fan FRU 602 such that cutout 628 is located adjacent to lip 1516 and threaded mounting pin 612 is inserted into aperture 1520. Generally, sidewall divider mounting bracket 1506 is complementary in shape to cutout 628 such that sidewall divider mounting bracket 1506 fits within and fills cutout 628. Module sides 306, 308 are sandwiched between and abut adjacent central plates 1504 of adjacent sidewall dividers 1502. Knob 630 of threaded mounting pin 612 is then twisted by the user to thread threaded mounting pin 612 into aperture 1520 thus locking Z-stepped parallel fan FRU 602 to sidewall divider 1502 and generally into electronic device 100. This operation is reversed to remove Z-stepped parallel fan FRU 602.

Once mounted in place, central plate 1504 performs as an air diversion plate thus further defining airflow pathway 318 between second fan 314 and central plate 1504.

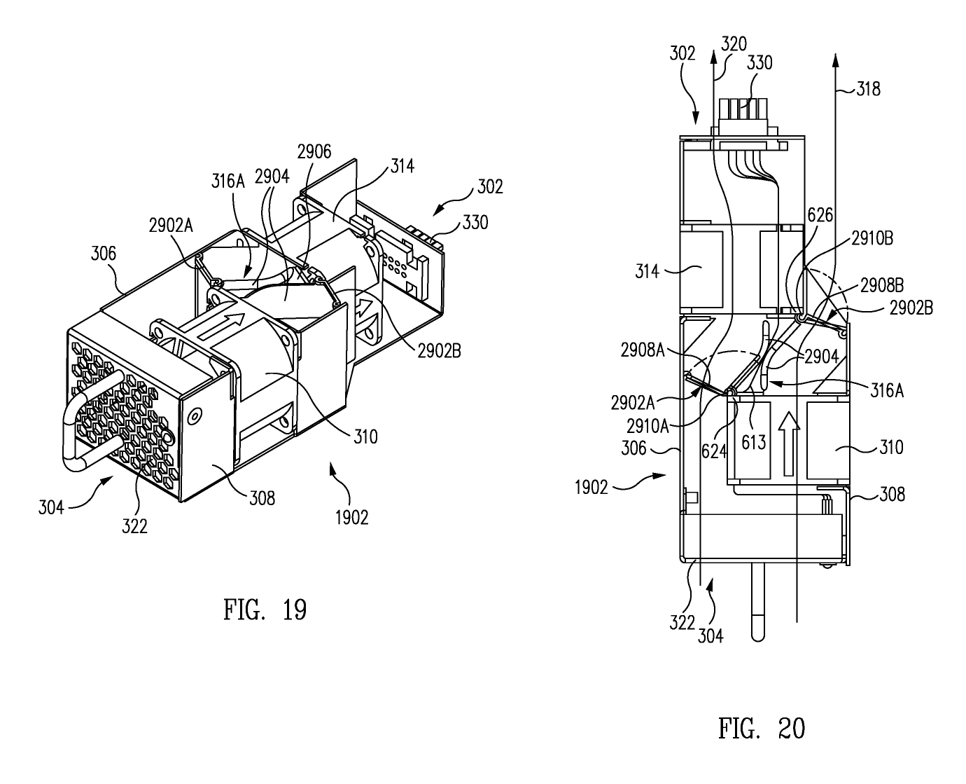

FIGS. 19-20 are perspective and top plan views, respectively, of a Z-stepped parallel fan FRU 1902 having reverse air flow restrictors 2902A, 2902B for restricting reverse airflow upon a fan failure condition in accordance with one embodiment. Z-stepped parallel fan FRU 1902 is similar to Z-stepped parallel fan FRUs 102, 602 as described above and only the significant differences are discussed below.

In accordance with this embodiment, a baffle 316A includes two sculpted fan ducts 2904 to minimize flow restrictions and allow for cable routing (wiring 613) in a protected channel 2906. Further, reverse air flow restrictors 2902A, 2902B operate as check valves allowing air to flow in one direction only.

More particularly, reverse air flow restrictors 2902A, 2902B include pivot plates 2908A, 2908B which can pivot around pivot points 2910A, 2910B, e.g., pivot pins. In accordance with this embodiment, reverse air flow restrictor 2902A is pivotally coupled to or adjacent edge 624 of first fan 310. During normal operation of second fan 314, air flow forces reverse air flow restrictor 2902A against baffle 316A thus unobstructing (maintaining patency of) air flow pathway 320. However, upon failure of second fan 314 and in the event of reverse airflow along air flow pathway 320, reverse air flow restrictor 2902A is forced away from baffle 316A to extend across and seal air flow pathway 320. In this manner, reverse air flow restrictor 2902A restricts reverse air flow upon failure of second fan 314.

Similarly, reverse air flow restrictor 2902B is pivotally coupled to or adjacent edge 626 of second fan 314. During normal operation of first fan 310, an flow forces reverse or flow restrictor 2902B against second fan 314 thus unobstructing (maintaining patency of) air flow pathway 318. However, upon failure of first fan 310 and in the event of reverse airflow along air flow pathway 318, reverse air flow restrictor 2902B is forced away from second fan 314 to extend across and seal air flow pathway 318. In this manner, reverse air flow restrictor 2902B restricts reverse air flow upon failure of first fan 310.

The drawings and the forgoing description gave examples of embodiments. The scope of the embodiments, however, is by no means limited by these specific examples. Numerous variations, whether explicitly given in the specification or not, such as differences in structure, dimension, and use of material, are possible.

What is claimed is:

1. A fan module comprising:
a front face;
a rear face;
a first fan comprising a front face fan port facing towards the front face;
a second fan comprising a rear face fan port facing towards the rear face, the first fan being between the rear face and the second fan;
a baffle isolating the front face fan port of the first fan from the rear face fan port of the second fan; and
a module port at the rear face and spaced apart from the first fan.

2. The fan module of claim 1 further comprising:
a first module side, an outer side of the second fan being located at the first module side; and
a second module side, an outer side of the first fan being located as the second module side.

3. The fan module of claim 2 wherein the first fan overlaps the second fan such that a width of the fan module is less than a combined width of the first fan and the second fan.

4. The fan module of claim 2 wherein the baffle extends from an edge of the first fan to an edge of the second fan.

5. The fan module of claim 4 wherein the edge of the first fan is at air intersection of an inner side of the first fan and the front face fan port; and
wherein the edge of the second fan is at an intersection of an inner side of the second fan and the rear face fan port.

6. The fan module of claim 5 wherein the inner side of the first fan is spaced apart from the first module side, and
wherein the inner side of the second fan is spaced apart from the second module side.

7. The fan module of claim 1 further comprising:
a first fan airflow pathway; and
a second fan airflow pathway, the first fan airflow pathway being parallel to the second fan airflow pathway.

8. The fan module of claim 7 wherein the first fan airflow pathway extends through the first fan and the second fan airflow pathway extends through the second fan.

9. The fan module of claim 8 wherein the first fan and the second fan are axial fans.

10. The fan module of claim 7 further comprising:
reverse air flow restrictors configured to prevent reverse air flow along the first fan airflow pathway and the second fan airflow pathway.

11. An electronic device comprising:
a fan module comprising:
a first fan;
a second fan;
a baffle isolating a front face fan port of the first fan from a rear face fan port of the second fan;
a threaded mounting pins, and
a sidewall divider configured to engage the threaded mounting pin.

12. The electronic device of claim 11 wherein the fan module further comprises a fan chassis base having a cutout therein, the sidewall divider further comprising a sidewall divider mounting bracket complimentary in shape to the cutout.

13. The electronic device of claim 12 wherein the sidewall divider mounting bracket fits within the cutout.

14. The electronic device of claim 12 wherein the sidewall divider mounting bracket comprises a taper configured to guide the fan module.

15. The electronic device of claim 12 further comprising a chassis base, the sidewall divider mounting bracket being mounted to the chassis base.

16. The electronic device of claim 11 wherein the sidewall divider comprises:
a central plate; and
a fan field replaceable unit (FRU) mounting bracket extending from the central plate, the threaded mounting pin being configured to be threaded into an aperture of the fan FRU mounting bracket.

17. The electronic device of claim 11 further comprising a cover, wherein the sidewall divider comprises a cover mounting bracket, the cover being mounted to the cover mounting bracket.

18. A method comprising:
creating a first fan airflow pathway and a parallel second fan airflow pathway through a fan module, the fan module comprising a first module side and a second module side,
wherein the first fan airflow pathway extends from a module port at a rear face of the fan module to a first fan, through the first fan, between a baffle and the second module side, and between a second fan and the second module side; and
wherein the second fan airflow pathway extends from the module port and between the first fan and the first module side, between the baffle and the first module side, and through the second fan.

19. The method of claim 18 further comprising mounting the fan module within an electronic device comprising:
fitting a sidewall divider mounting bracket of a sidewall divider within a cutout of the fan module; and
threading a threaded mounting pin into an aperture of a fan field replaceable unit (FRU) mounting bracket of the sidewall divider.

20. The method of claim 18 further comprising preventing reverse airflow along the first fan airflow pathway and the second fan airflow pathway.
